(19) United States
(12) Patent Application Publication
(10) Pub. No.: US 2005/0268955 A1
(43) Pub. Date: Dec. 8, 2005

(54) Diesel-electric locomotive engine waste heat recovery system

(76) Inventors: Daniel J. Meyerkord, Burr Ridge, IL (US); David J. Goding, Palos Park, IL (US)

Correspondence Address: CARY W. BROOKS;General Motors Corporation, Legal Staff, Mail Code 482-C23-B21, P.O. Box 300, Detroit, MI, 48265-3000, US

(21) Appl. No.: 11/029,077

(22) Filed: Jan. 4, 2005

Related U.S. Application Data
(60) Provisional application No. 60/577,966, filed on Jun. 8, 2004.

(51) Int. Cl. H01L 35/28; F25B 21/02; H01L 35/30

(52) U.S. Cl. 136/205; 136/212

(57) ABSTRACT

A locomotive diesel engine waste heat recovery system for converting waste heat of engine combustion into useful work. A thermoelectric module is connected to the hot engine exhaust to provide a high temperature heat source, and the engine coolant system is also connected to the thermoelectric module to provide a low temperature heat source. The difference in temperature of the heat sources powers the thermoelectric module to convert waste heat of the engine into electricity to power selected devices of the locomotive.

### CROSS-REFERENCE TO RELATED APPLICATIONS

The present patent application claims the benefit of provisional patent application Ser. No. 60/577,966, filed on Jun. 8, 2004.

### TECHNICAL FIELD

The present invention relates to diesel-electric locomotives, and more particularly to a locomotive waste energy recovery system including a thermoelectric device.

### BACKGROUND OF THE INVENTION

In most modern railroad diesel-electric locomotives, the diesel engine drives an electric generator which in turn provides electrical power to motors which are mechanically geared to the locomotive wheels. The diesel engine is typically turbocharged. The turbocharger provides charge air for the diesel engine fuel combustion. In this regard, combustion exhaust gas provides work of expansion across a turbine section of the turbocharger which, in turn, provides rotational energy to the compressor section of the turbocharger so as to produce the charge air for combustion. The exhaust gas from the turbocharger is discharged into the atmosphere, wherein the heat thereof is dumped to the atmosphere.

In operation, the locomotive is typically operated at a set of throttle notches, each of which defines a specific engine load and speed. As the engine operates, the combustion process generates waste heat which must be removed from the engine. In this regard, locomotive diesel engines have a coolant system in which a liquid coolant is circulated within the engine so as to transport heat from engine components (as, for example, cylinder liners, heads, oil coolers, etc.) to radiators where the heat is discharged to the atmosphere (surrounding air).

An increasing awareness of energy conservation and preservation of the environment has renewed interest in applications of thermoelectric devices because thermoelectric devices can transform heat directly into electrical energy and can also act as solid state refrigerators.

Historically, due to its low cooling coefficient of performance and energy conversion efficiency, thermoelectric technology has seen limited use. The efficiency characteristics of a thermoelectric device are determined by the thermoelectric material's figure of merit, ZT.

Prior to 1990, the highest ZT values of all thermoelectric materials remained below one. The combination of increased U.S. government funding and private enterprise research and development have led to significant increases in ZT values in recent years which has stimulated interest in thermoelectric technology applications. There has now emerged a large variety of new high efficiency thermoelectric materials that cover a wide temperature range, thereby allowing further design flexibility for locomotive applications.

Accordingly, what remains needed in the art is to devise some way that thermoelectric devices could help to increase the ability of locomotive diesel engines to convert diesel fuel combustion waste heat into useful work, thereby minimizing waste heat rejected to the atmosphere, and increasing locomotive fuel efficiency by as much as 10 percent.

### SUMMARY OF THE INVENTION

The present invention is a system which recovers waste heat generated by a locomotive diesel engine by utilization of a thermoelectric device connected to a source of waste heat of the engine to thereby convert this waste heat into additional electricity or other useful work (as, for example, air conditioning) to the locomotive.

The present invention is a locomotive diesel engine waste heat recovery system consisting of a thermoelectric module thermally interfaced with the waste heat of the engine and electrically interfaced with selected electrical components. Any source of waste heat of the diesel engine serves as a high temperature heat source for the thermoelectric module, and any source of cooler temperature serves as the low temperature heat source for the thermoelectric module, wherein the difference in temperatures therebetween powers the thermoelectric module to provide conversion of the waste heat into useful work, particularly electricity.

In the most preferred embodiment, the thermoelectric module is preferably located adjacent to, or integral with, the turbocharger exhaust gas duct such that the high temperature exhaust gas exiting therefrom is directed through a first chamber of the thermoelectric module, thus providing a high temperature heat source for the thermoelectric module. The atmosphere ultimately provides the low temperature heat source for the thermoelectric device, most preferably by the diesel engine coolant circuit having a loop passing through a second chamber of the thermoelectric module. The temperature differential provided between the hot and low temperature heat sources, the hot exhaust gas and the cooler liquid coolant, provides energy to drive the thermoelectric process at the thermoelectric module so as to output therefrom electrical energy which is used for powering selected components of the locomotive. For example, the electrical energy is routed to the locomotive power management module where it is then conditioned for use in powering locomotive electrical equipment such as fans, blowers, and other ancillary equipment, and/or for powering locomotive traction power drives.

Accordingly, it is an object of the present invention to provide a waste heat recovery system for a locomotive diesel engine utilizing a thermoelectric module to convert waste heat of the engine into useful work, particularly electricity.

This and additional objects, features and advantages of the present invention will become clearer from the following specification of a preferred embodiment.

### BRIEF DESCRIPTION OF THE DRAWINGS

FIG. 1 is a flow chart schematic of a waste energy recovery system for a locomotive diesel engine according to the present invention.

FIG. 2A is a schematic view of a most preferred waste energy recovery system for a locomotive diesel engine according to the present invention.

FIG. 2B is an alternative schematic view of the waste energy recovery system of FIG. 2A for a locomotive diesel engine according to the present invention.

FIG. 3 is a schematic view of a thermoelectric module for the waste energy recovery system of FIGS. 2A and 2B.

FIG. 4 is a schematic view of a first alternative embodiment of a waste energy recovery system for a locomotive diesel engine according to the present invention.

FIG. 5 is a schematic view of a thermoelectric module for the waste energy recovery system of FIG. 4.

FIG. 6 is a schematic view of a second alternative embodiment of a waste energy recovery system for a locomotive diesel engine according to the present invention.

FIG. 7 is a schematic view of a thermoelectric module for the waste energy recovery system of FIG. 6.

### DESCRIPTION OF THE PREFERRED EMBODIMENTS

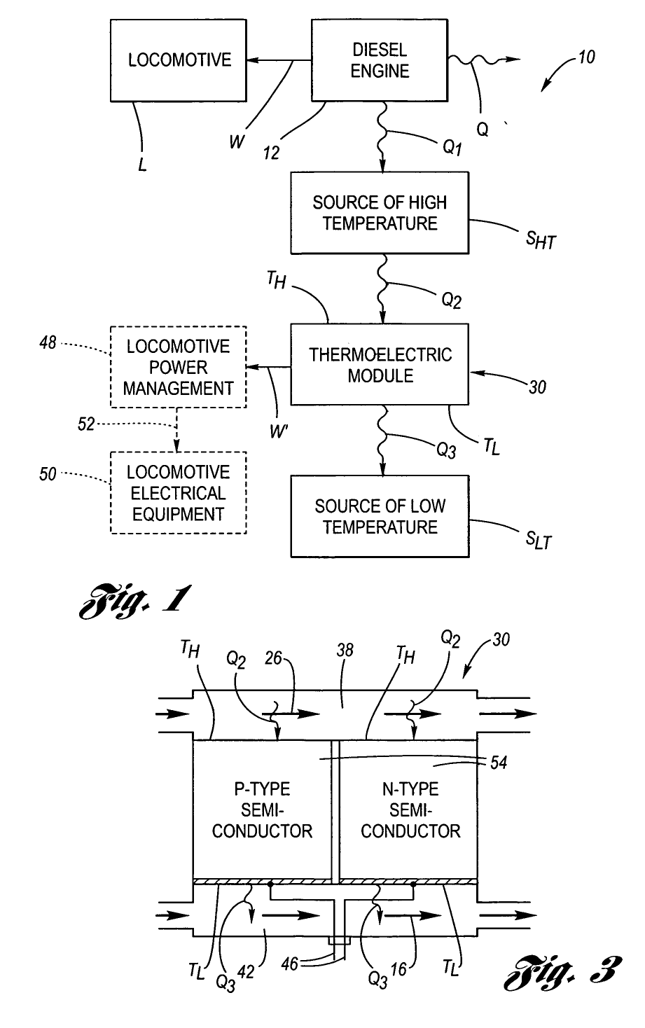

Referring now to the drawings, wherein in the various views like numbers refer to like functioning components, FIG. 1 depicts a flow chart schematic of a locomotive diesel engine waste heat recovery system 10. The diesel engine 12 combusts fuel and produces work W for powering the locomotive L and also produces waste heat. A portion of the waste heat Q is dumped to the atmosphere, and another portion of the waste heat Q₁ provides a source of high temperature S_{HT}. The heat from the source of high temperature S_{HT} is exposed to one side of a thermoelectric module 30 and supplies heat Q₂ thereto so as to provide a high temperature heat source T_{H} thereat. A source of low temperature S_{LT}, as for example engine coolant or the atmosphere itself, is in contact with an opposite side of the thermoelectric module and extracts heat Q₃ so as to provide a low temperature heat source T_{L} thereat. The high temperature heat source T_{H} has a higher temperature than that of the low temperature heat source T_{L}, and the difference in temperatures of the high and low temperature heat sources T_{H}, T_{L} causes the thermoelectric module 30 to provide a useful work output W′, which can be for example refrigeration or electricity. Where electricity is output, it is preferred for the electricity to go into a locomotive power management module 48 where it is conditioned for use to power, via electrical connections 52, various locomotive electrical equipment 50.

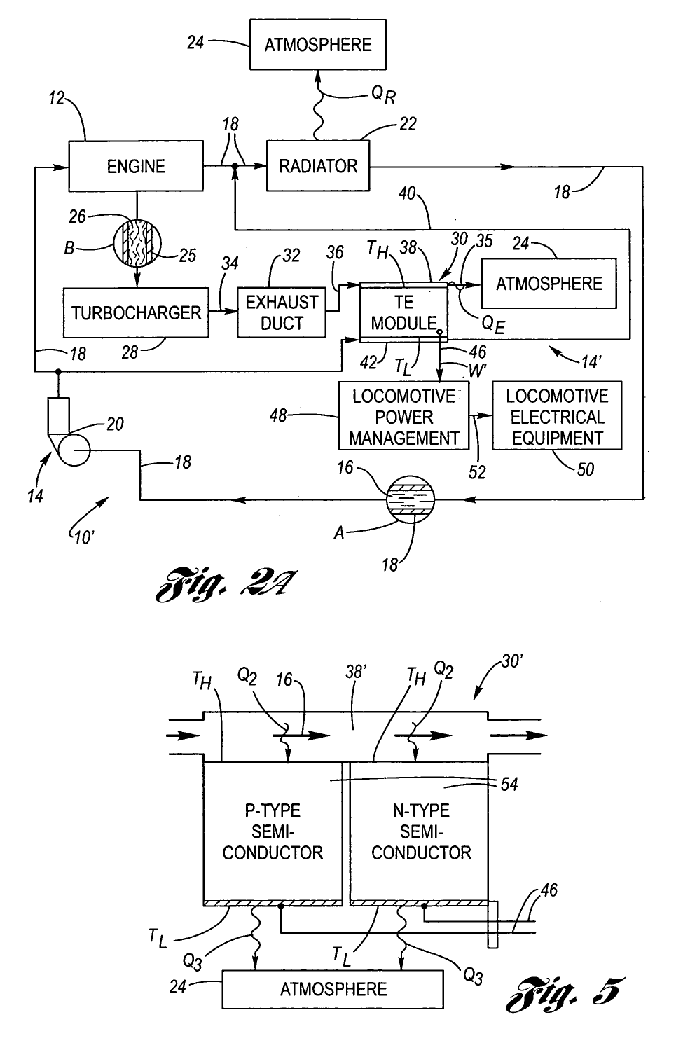

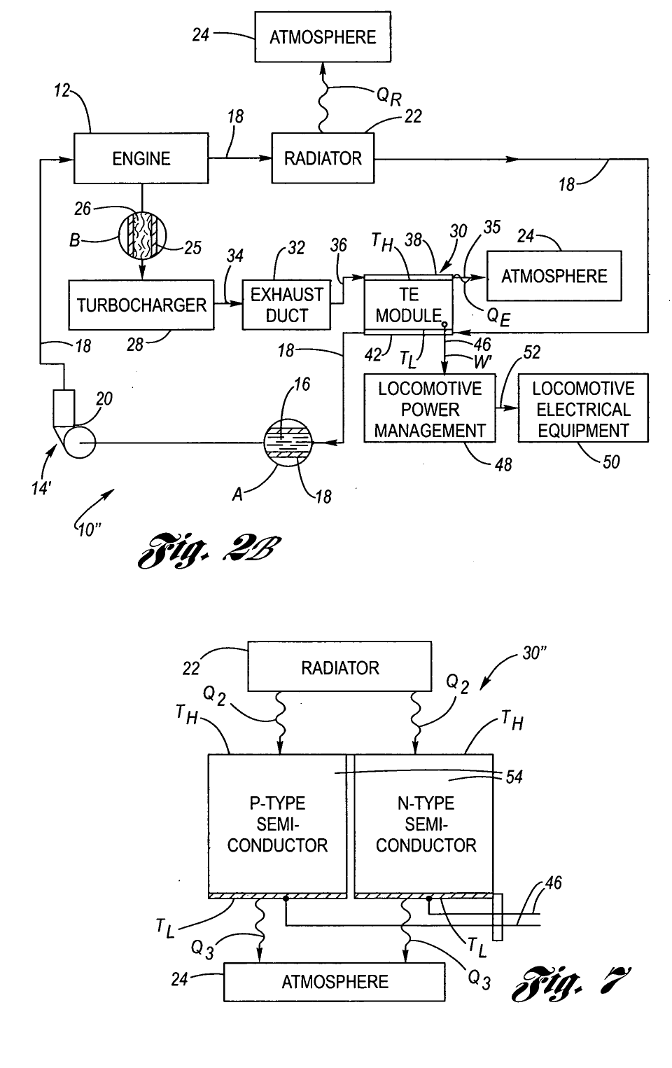

Referring now to FIGS. 2A through 3, depicted is a schematic representation of a preferred locomotive diesel engine waste heat recovery system 10′, 10″ according to the present invention.

In order to remove the waste heat from the diesel engine 12, a coolant system 14 is provided, which includes liquid coolant 16 which flows through coolant conduits 18 at the urging of a pump 20 so that the coolant flows through predetermined passages within the engine and also through a radiator 22, whereat heat Q_{R} is rejected to the atmosphere 24. Thus, at the engine the coolant 16 (see detail inset circle A) absorbs heat of combustion from the engine 12 and rejects heat Q_{R} at one or more radiators 22 to the atmosphere 24.

The combustion process of the diesel engine 12 also produces hot exhaust gas 26. This hot exhaust gas 26 is conventionally dumped to the atmosphere, preferably after going through a turbine section of a turbocharger 28. However, the locomotive diesel engine waste heat recovery system 10′, 10″ according to the present invention utilizes this hot exhaust gas 26 as a source of high temperature which provides a high temperature heat source T_{H} for a thermoelectric module 30.

The turbocharger 28 provides charge air for fuel combustion in the diesel engine 12. In this regard, the exhaust gas 26 is piped 25 (see detail inset circle B) to provide work of expansion across a turbine section of the turbocharger which, in turn, provides rotational energy to the compressor section of the turbocharger so as to produce the charge air for combustion. The thermoelectric module 30 is preferably located adjacent to, or integral with, an exhaust gas duct 32 connected 34 to the turbocharger 28, and is connected 36 to a first chamber 38 of the thermoelectric module (see detail at FIG. 3). Accordingly, the high temperature exhaust gas 26 exiting from the diesel engine 12 provides the high temperature heat source T_{H} for delivering heat Q₂ to the thermoelectric module 30. Thereafter, the exhaust gas 26 vents 35 and thereby dumps heat Q_{E} to the atmosphere 24, wherein the exhaust gas is cooler because some of the heat energy thereof has been converted into a useful work output W′ (i.e., electricity) by the thermoelectric module 30.

The atmosphere 24 ultimately provides a source of low temperature for the low temperature heat source T_{L} for extracting heat Q₃ from the thermoelectric module 30. It is preferred to provide the low temperature heat source T_{L} by utilization of the coolant 16 of the coolant system 14 having a connection to a second chamber 42 of the thermoelectric module 30 (see detail at FIG. 3). In FIG. 2A (which is most preferred) a coolant loop 14′ is provided by conduits 40 connected to conduits 18 of the coolant system 14. The coolant loop conduits 40 interface with an outside wall 42 of the thermoelectric module 30 to thereby provide the low temperature heat source T_{L} therefor. In FIG. 2B, there is no coolant loop in the coolant system 14′, wherein the second chamber 42 of the thermoelectric module 30 is now located downstream of the radiator 22 (that is, after the coolant 16 has been cooled by passing through the radiator).

As best seen at FIG. 3, the thermoelectric module is composed of semiconductor thermoelectric materials 54, P-Type and N-Type, wherein, for example, a first side thereof the thermoelectric materials absorbs heat Q₂ because it is exposed the high temperature heat source T_{H} and the opposite, second side thereof rejects heat Q₃ because it is exposed to the low temperature heat source T_{L}. Electrical connections to the second side provide an electrical output from the thermoelectric materials. It is preferred for the thermoelectric materials to be the most efficient known, as for nonlimiting example described in U.S. Ser. No. 10/836,643, filed on Apr. 30, 2004, the disclosure of which is hereby herein incorporated by reference.

The temperature differential provided between the hot and low temperature heat sources T_{H}, T_{L} (the hot exhaust gas 26 and the cooler liquid coolant 16), drives the thermoelectric process at the thermoelectric module 30 so as to provide a work output W′ such as refrigeration or electrical energy, wherein in the preferred form of electrical energy, the electricity is used for powering locomotive electrical equipment. For preferable example, the electrical energy is routed, via an electrical connection 46, to the locomotive power management module 48, where it is then conditioned for use in powering locomotive electrical equipment 50, such as for example fans, blowers, and other ancillary equipment, and/or locomotive tractive power devices, via electrical connections 52.

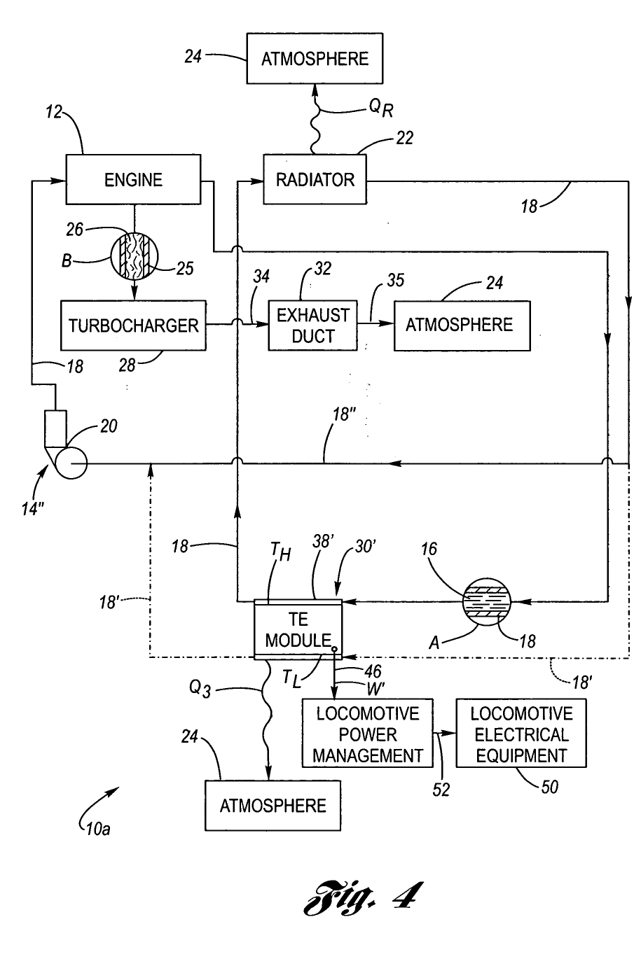

Any waste heat source of the locomotive diesel engine 12 may be utilized for operating the thermoelectric module, as per the example of FIG. 1. In this regard, FIGS. 4 through 7 depict nonlimiting examples of waste heat conversion to useful work additional to the foregoing description with regard to FIGS. 2A through 3.

FIGS. 4 and 5 depict a locomotive diesel engine waste heat recovery system 10a according to the present invention, wherein the coolant system 14″ provides the high temperature heat source T_{H} for supplying heat Q₂ to the thermoelectric module 30′, and wherein the first chamber 38′ now has coolant 16 passing therethrough which has exited the engine, preferably before passing through the radiator 22 so that it is in its hottest state. In this embodiment, heat Q₃ is extracted to the atmosphere 24, wherein the atmosphere directly supplies the low temperature heat source T_{L}. This could be accomplished, for example, by radiative fins on the second side (the low temperature heat source T_{L} side) of the thermoelectric materials 54. Alternatively, for example, the coolant immediately exiting the radiator which is cooler than the coolant immediately exiting the engine, can be used as the low temperature heat source T_{L} to extract heat [see the alternative portion 18″, shown in phantom, of the coolant conduits 18 which would, in that case, replace the intermediate portion 18′ (situated between the ends of the alternative portion 18″) of the coolant conduits].

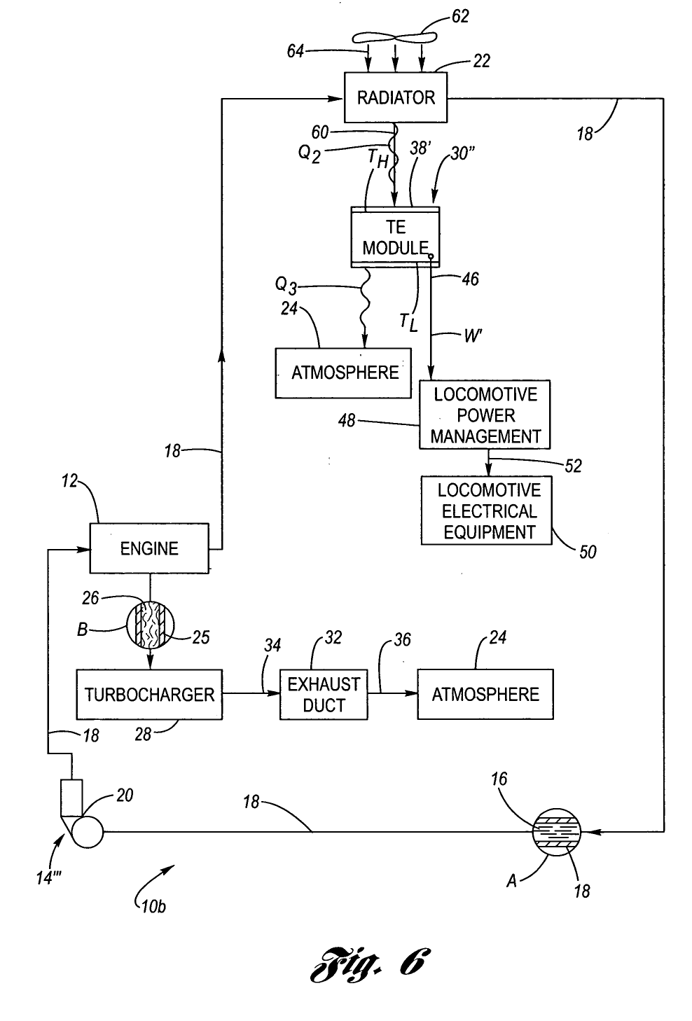

FIGS. 6 and 7 depict a locomotive diesel engine waste heat recovery system 10b according to the present invention. A fan 62 provides blown air 64 which passes through the radiator 22 of the coolant system 14′″, creating a stream of hot air 60 which thereby provides the high temperature heat source T_{H} for the thermoelectric module 30″ to absorb heat Q₂. As in the embodiment of FIGS. 4 and 5, heat Q₃ is extracted to the atmosphere, wherein the atmosphere directly supplies the low temperature heat source T_{L}. Again, this could be accomplished, for example, by radiative fins on the second side (the low temperature heat source T_{L} side) of the thermoelectric materials 54.

To those skilled in the art to which this invention appertains, the above described preferred embodiment may be subject to change or modification. Such change or modification can be carried out without departing from the scope of the invention, which is intended to be limited only by the scope of the appended claims.

1. A locomotive diesel engine waste heat recovery system, comprising:
a locomotive diesel engine producing waste heat of combustion during operation, wherein said waste heat is hotter than a temperature of the atmosphere;
a thermoelectric module interfaced with said waste heat, wherein said waste heat provides a high temperature heat source for said thermoelectric module; and
a low temperature heat source interfaced with said thermoelectric module, wherein a temperature difference between said high and low temperature heat sources results in said thermoelectric module producing a work output.

2. The locomotive diesel engine waste heat recovery system of claim 1, wherein said work output comprises electrical energy; said locomotive diesel engine waste heat recovery system further comprising:
a locomotive power management module; and
locomotive electrical equipment;
wherein said locomotive power management module conditions said electrical energy from said thermoelectric module so that the conditioned electrical energy electrically powers said locomotive electrical equipment.

3. The locomotive diesel engine waste heat recovery system of claim 1, further comprising a coolant system connected to said locomotive diesel engine for transporting said waste heat from said locomotive diesel engine and rejecting said waste heat to the atmosphere, wherein said high temperature heat source is provided by a connection of said coolant system to said thermoelectric module.

4. The locomotive diesel engine waste heat recovery system of claim 3, further comprising:
a locomotive power management module; and
locomotive electrical equipment;
wherein said locomotive power management module conditions said electrical energy from said thermoelectric module so that the conditioned electrical energy electrically powers said locomotive electrical equipment.

5. The locomotive diesel engine waste heat recovery system of claim 1, further comprising a coolant system connected to said locomotive diesel engine for transporting said waste heat from said locomotive diesel engine and rejecting the waste heat to the atmosphere, said coolant system further comprising a radiator and a fan blowing air therethrough so as to provide a stream of hot air, wherein said stream of hot air contacts said thermoelectric module so as to thereby provide said high temperature heat source therefor.

6. The locomotive diesel engine waste heat recovery system of claim 5, further comprising:
a locomotive power management module; and
locomotive electrical equipment;
wherein said locomotive power management module conditions said electrical energy from said thermoelectric module so that the conditioned electrical energy electrically powers said locomotive electrical equipment.

7. The locomotive diesel engine waste heat recovery system of claim 1, wherein said locomotive diesel engine produces exhaust gas of combustion during operation, wherein said exhaust gas is hotter than a temperature of the atmosphere, wherein said high temperature heat source is provided by a connection of said exhaust gas to said thermoelectric module.

8. The locomotive diesel engine waste heat recovery system of claim 7, further comprising:
a locomotive power management module; and
locomotive electrical equipment;
wherein said locomotive power management module conditions said electrical energy from said thermoelectric module so that the conditioned electrical energy electrically powers said locomotive electrical equipment.

9. A locomotive diesel engine waste heat recovery system, comprising:
a locomotive diesel engine producing exhaust gas of combustion during operation, wherein said exhaust gas is hotter than a temperature of the atmosphere;
a thermoelectric module interfaced with said exhaust gas, wherein said exhaust gas provides a high temperature heat source for said thermoelectric module; and
a low temperature heat source interfaced with said thermoelectric module, wherein a temperature difference between said high and low temperature heat sources results in said thermoelectric module producing electrical energy.

10. The locomotive diesel engine waste heat recovery system of claim 9, further comprising:
a locomotive power management module; and
locomotive electrical equipment;
wherein said locomotive power management module conditions said electrical energy from said thermoelectric module so that the conditioned electrical energy electrically powers said locomotive electrical equipment.

11. The locomotive diesel engine waste heat recovery system of claim 9, further comprising a coolant system connected to said locomotive diesel engine for transporting said waste heat from said locomotive diesel engine and rejecting said waste heat to the atmosphere, wherein said low temperature heat source is provided by a connection of said coolant system to said thermoelectric module.

12. The locomotive diesel engine waste heat recovery system of claim 11, wherein said coolant system further comprises a radiator, wherein said connection of said coolant system to said thermoelectric module is located downstream of said radiator.

13. The locomotive diesel engine waste heat recovery system of claim 12, further comprising:
a locomotive power management module; and
locomotive electrical equipment;
wherein said locomotive power management module conditions said electrical energy from said thermoelectric module so that the conditioned electrical energy electrically powers said locomotive electrical equipment.

14. The locomotive diesel engine waste heat recovery system of claim 11, wherein said coolant system further comprises a pump and a radiator, wherein the low temperature heat source is provided by a coolant loop connected to said thermoelectric module, said coolant loop including said pump and said radiator and excluding said locomotive diesel engine.

15. The locomotive diesel engine waste heat recovery system of claim 14, further comprising:
a locomotive power management module; and
a plurality of electrical devices;
wherein the locomotive power management module conditions the electrical energy from said thermoelectric module so that the electrical energy electrically powers the plurality of electrical devices.

16. A locomotive diesel engine waste heat recovery system, comprising:
a locomotive diesel engine producing work and waste heat during operation, wherein said waste heat is hotter than a temperature of the atmosphere;
a thermoelectric module interfaced with said waste heat, wherein said waste heat provides a high temperature heat source for said thermoelectric module;
a low temperature heat source interfaced with said thermoelectric module, wherein a temperature difference between said high and low temperature heat sources results in said thermoelectric module producing electrical energy;
a locomotive power management module; and
locomotive electrical equipment;
wherein said locomotive power management module conditions said electrical energy from said thermoelectric module so that the conditioned electrical energy electrically powers said locomotive electrical equipment.
